(19) United States
(12) Patent Application Publication
(10) Pub. No.: US 2013/0153886 A1
(43) Pub. Date: Jun. 20, 2013

(54) SEMICONDUCTOR DEVICE AND MANUFACTURING METHOD THEREOF

(71) Applicants: Edward Yi. Chang, Hsinchu County (TW); Yueh-Chin Lin, Hsinchu City (TW); Chia-Hua Chang, Taichung City (TW); Hai-Dang Trinh, Hsinchu City (TW)

(72) Inventors: Edward Yi. Chang, Hsinchu County (TW); Yueh-Chin Lin, Hsinchu City (TW); Chia-Hua Chang, Taichung City (TW); Hai-Dang Trinh, Hsinchu City (TW)

(73) Assignee: NATIONAL CHIAO TUNG UNIVERSITY, HSINCHU CITY (TW)

(21) Appl. No.: 13/477,868

(22) Filed: May 22, 2012

(30) Foreign Application Priority Data
Dec. 15, 2011 (TW) 100146641

(51) Int. Cl. H01L 29/12; H01L 21/02

(52) U.S. Cl. 257/43; 438/104; 257/E29.068; 257/E21.002

(57) ABSTRACT

The present invention relates to a semiconductor device and a manufacturing method thereof. The semiconductor device includes: a III-V semiconductor layer; an aluminum oxide layer formed on the III-V semiconductor layer; and a lanthanide oxide layer formed on the aluminum oxide layer. The method of manufacturing a semiconductor device includes: forming an aluminum oxide layer between a III-V semiconductor layer and a lanthanide oxide layer so as to prevent an inter-reaction of atoms between the III-V semiconductor layer and the lanthanide oxide layer.

The application claims the benefit of ROC Patent Application No. 100146641, filed on Dec. 15, 2011, in the Intellectual Property Office of Republic of China, the disclosures of which is incorporated by reference as if fully set forth herein.

### FIELD OF THE INVENTION

The present invention relates to a semiconductor device. More particularly, it relates to a semiconductor device with an aluminum oxide layer to inhibit/prevent the inter-reaction of atoms between a semiconductor layer and a dielectric layer.

### BACKGROUND OF THE INVENTION

With the development of the technology, the size of an integrated circuit is getting smaller and the requirement of the high density unit capacity is increasing. Recently, III-V semiconductors are widely researched because a III-V semiconductor has a better material property than that of a Si semiconductor. For example, a III-V Metal-Oxide-Semiconductor Field Effect transistor (MOSFET) has a gate dielectric layer formed by depositing oxide onto a III-V semiconductor chip can be used to replace a conventional Si MOSET. However, if a high-κ oxide is deposited on a III-V semiconductor, the inter-reaction of atoms between the high-κ oxide and the III-V semiconductor will result in a higher current leakage, so as to make the electrical property of the capacitor in the III-V MOSFET invalid. For example, La₂O₃, Pr₆O₁₁ and CeO₂ have dielectric constants higher than 30, and once La₂O₃, Pr₆O₁₁ or CeO₂ is directly deposited on InGaAs semiconductor, after annealing at a high temperature, La₂O₃, Pr₆O₁₁ or CeO₂ will result in the interdiffusion with the InGaAs such that the electrical property of the capacitor in the III-V MOSFET fails.

Please refer to FIGS. 1A and 1B which show the Capacitance-Voltage (C-V) curve diagram and the Current Density-Voltage (J-V) curve diagram of the La₂O₃(12 nm)-In_{0.53}Ga_{0.47}As MOS capacitor. The above diagrams show the C-V characteristic and the gate current leakage characteristic measured after directly depositing 12 nm La₂O₃ on a III-V semiconductor and annealing at 500° C. for 1 minute. In FIG. 1A, it shows the dispersed capacitances in InGaAs capacitor at different operating frequencies (i.e. frequency dispersion) and the lack of strong inversion. Namely, the electrical property of the capacitor is invalid/fails. In FIG. 1B, it is observed that the InGaAs has a large gate leakage current (more than 1000 A/cm²) in the investigated range. In other words, depositing a high-κ oxide on a III-V semiconductor will cause a larger leakage current.

Thus, if one wants to deposit a high-κ oxide, such as La₂O₃, Pr₆O₁₁, CeO₂ and so on, on a III-V semiconductor to improve the equivalent oxide thickness (EOT) of a III-V Metal-Oxide-Semiconductor device, the failure of the electrical property must be overcome in advance.

Therefore, it would be useful to invent a semiconductor device to circumvent all the above issues. In order to fulfill this need the inventors have proposed an invention “SEMICONDUCTOR DEVICE AND MANUFACTURING METHOD THEREOF.” The summary of the present invention is described as follows.

### SUMMARY OF THE INVENTION

The present invention is to deposit a dielectric layer having an oxide with a high dielectric constant in order to improve the EOT of the device. However, high-κ materials, such as a lanthanide oxide, will result in the interdiffusion between the oxide and the semiconductor when annealing at a high temperature, and thus the interface is unstable which causes the failure of the electrical property of the semiconductor device. Therefore, the present invention provides the technical scheme that uses Al₂O₃ as a barrier layer to prevent/inhibit the inter-reaction between the high-κ oxide and the III-V semiconductor, and hence can improve the EOT of the semiconductor device.

According to the first aspect of the present invention, a metal-oxide-semiconductor device includes a III-V semiconductor layer; an aluminum oxide layer formed on the III-V semiconductor layer; and a lanthanide oxide layer formed on the aluminum oxide layer.

According to the second aspect of the present invention, a semiconductor device includes: a semiconductor layer; a dielectric layer disposed on the semiconductor layer, wherein there is an inter-reaction of atoms between the semiconductor layer and the dielectric layer; and an aluminum oxide layer disposed between the semiconductor layer and the dielectric layer so as to inhibit the inter-reaction of atoms between the semiconductor layer and the dielectric layer.

According to the third aspect of the present invention, a method of manufacturing a semiconductor device includes steps of: providing a semiconductor layer and a dielectric layer; and forming an aluminum oxide layer between the semiconductor layer and the dielectric layer so as to prevent an inter-reaction of atoms between the semiconductor layer and the dielectric layer.

The foregoing and other features and advantages of the present invention will be more clearly understood through the following descriptions with reference to the drawings:

### BRIEF DESCRIPTION OF THE DRAWINGS

FIGS. 1A and 1B are diagrams showing the Capacitance-Voltage (C-V) curve and the Current Density-Voltage (J-V) curve of the La₂O₃(12 nm)-In_{0.53}Ga_{0.47}As MOS capacitor;

FIG. 2 is a diagram showing the structure of the first embodiment of the present invention;

FIG. 3 is a diagram showing the structure of the second embodiment of the present invention;

FIG. 4 is a diagram showing the flow of the method to manufacture the semiconductor device of the present invention;

FIG. 5 is a diagram showing the structure of the third embodiment of the present invention; and

FIG. 6 is a diagram showing the Capacitance-Voltage (C-V) curve diagram of the Al₂O₃/In_{0.53}Ga_{0.47}As MOS.

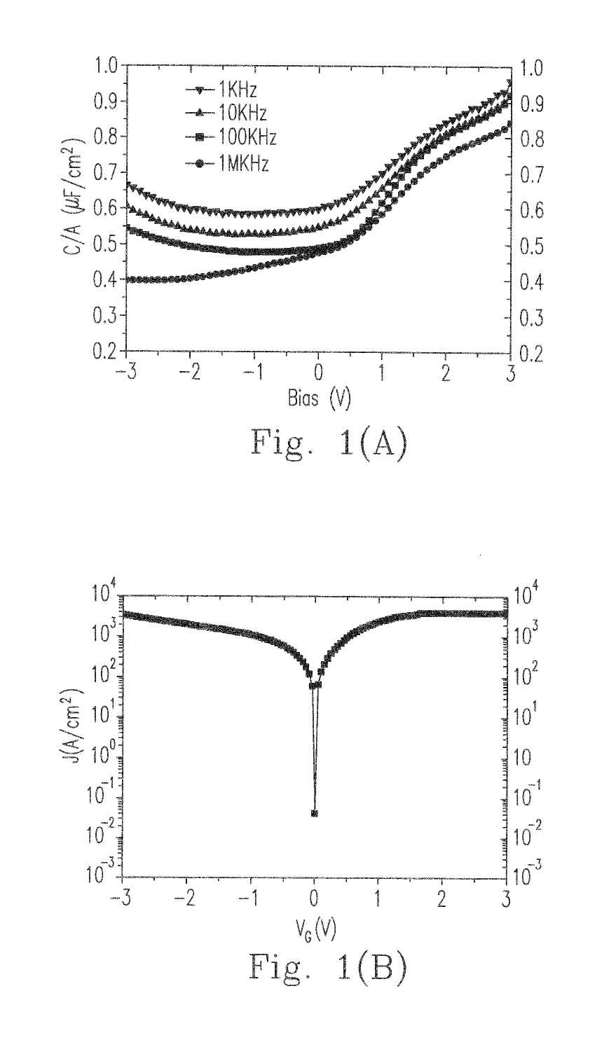

### DETAILED DESCRIPTION OF THE PREFERRED EMBODIMENT

The present invention will now be described more specifically with reference to the following embodiments. It is to be noted that the following descriptions of preferred embodiments of this invention are presented herein for the aspect of illustration and description only; it is not intended to be exhaustive or to be limited to the precise from disclosed.

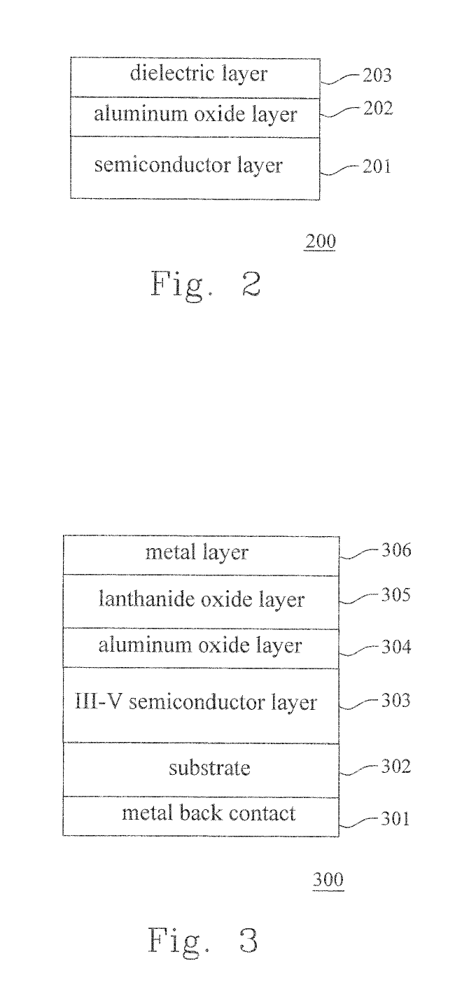

Please refer to FIG. 2 which shows the structure of the first embodiment of the present invention. The first embodiment is a semiconductor device 200. The semiconductor device 200 includes a semiconductor layer 201, an aluminum oxide layer 202 and a dielectric layer 203. There is an inter-reaction of atoms between the semiconductor layer and the dielectric layer to cause the interface between the semiconductor layer and the dielectric layer to be unstable which results in the failure of the electrical property of the semiconductor device. The structure technical feature of the present invention is that the aluminum oxide layer 202 is disposed between the semiconductor layer 201 and the dielectric layer 203 to prevent/inhibit the inter-reaction of atoms between the semiconductor layer and the dielectric layer. In other words, as long as there is an inter-reaction of atoms between any semiconductor layer and dielectric layer, we can prevent/inhibit the inter-reaction of atoms by using an aluminum oxide layer provided in the present invention in order to achieve the best EOT and solve the problem of failure of electrical property. In addition, the semiconductor layer 201 is preferably a III-V semiconductor layer, and the dielectric layer 203 is preferably a high-κ oxide layer, such as a lanthanide oxide, wherein the lanthanide elements includes La, Ce, Pr, Nd, Pm, Sm, Eu, Gd, Tb, Dy, Ho, Er, Tm, Yb and Lu. The semiconductor device 200 can be used as a capacitor, and the aluminum oxide layer 202 and the dielectric layer 203 can be used as a gate dielectric layer of a MOS device.

Please refer to FIG. 3 which shows the structure of the second embodiment of the present invention. The second embodiment is a MOS device 300. The MOS device 300, in order, includes a metal back contact 301, a substrate 302, a III-V semiconductor layer 303, an aluminum oxide layer 304, a lanthanide oxide layer 305 and a metal layer 306. The technical feature of the MOS device 300 is that the aluminum oxide layer 304 is used as a barrier to prevent/inhibit the inter-reaction of atoms between the III-V semiconductor layer 303 and the lanthanide oxide layer 305. The design of aluminum oxide/lanthanide composite oxide layer mainly utilizes depositing Al₂O₃ of higher energy bandgap on a III-V semiconductor to decrease the leakage current of a device, and a lanthanide oxide of a higher dielectric constant to decrease the EOT of gate oxide layer in the MOS device 300. In this embodiment, the III-V semiconductor layer 303 can be a GaAs layer, a GaN layer, an InAs layer, an InP layer, an InₓGa₁₋ₓAs layer and so on.

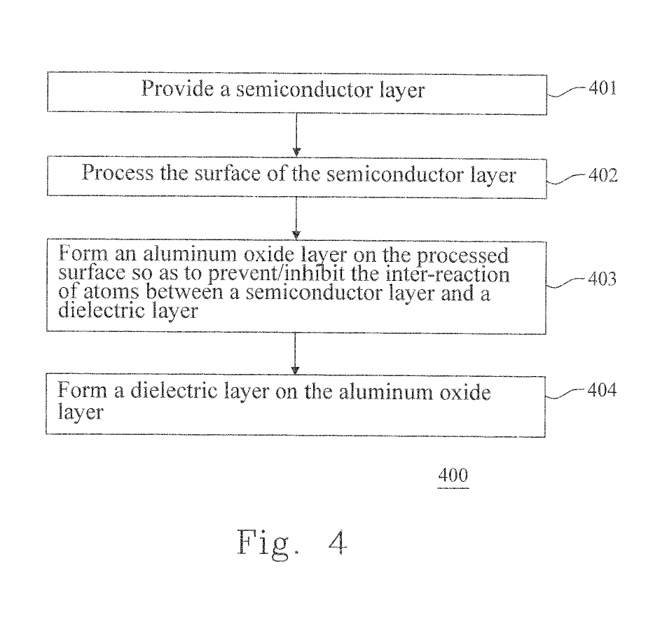

Please refer to FIG. 4 which shows the flow of the method to manufacture the semiconductor device of the present invention. The method 400 includes the following steps.

Step 401: Provide a semiconductor layer. Preferably, the semiconductor layer is a III-V semiconductor layer, especially an InₓGa₁₋ₓAs layer.

Step 402: Process the surface of the semiconductor layer. The purpose of this step is to make the semiconductor layer have a better surface property so as to facilitate the deposition of an aluminum oxide.

Step 403: Form an aluminum oxide layer on the processed surface so as to prevent/inhibit the inter-reaction of atoms between a semiconductor layer and a dielectric layer.

Step 404: Form a dielectric layer on the aluminum oxide layer. Preferably, the dielectric layer is a high-κ oxide layer, especially a lanthanide oxide layer.

In sum, the most important step in this method to manufacture the semiconductor device is: forming an aluminum oxide layer between a semiconductor layer and a dielectric layer so as to prevent/inhibit the inter-reaction of atoms between the semiconductor layer and the dielectric layer.

Please referring to Table I, in order to reduce the EOT of a III-V semiconductor device, the high-κ oxide is usually chosen to function as a dielectric layer. However, as to oxide layers, an oxide with a higher dielectric constant always has a lower energy bandgap. Taking the oxides in Table I for example, the energy bandgap (Eg) of Al₂O₃ is 8.7 eV, and La₂O₃, Pr₆O₁₁ and CeO₂ have the dielectric constant which is higher than 30. Therefore, the aluminum oxide/lanthanide oxide (Pr₆O₁₁ and CeO₂) composite oxide layer provided in the present invention can utilize depositing Al₂O₃ of higher energy bandgap on a semiconductor to decrease the leakage current of a device, and La₂O₃, Pr₆O₁₁ or CeO₂ of higher dielectric constant to decrease the EOT of oxide layer in the III-V semiconductor device.

TABLE I

| Oxide | Al₂O₃ | La₂O₃ | Pr₆O₁₁ | CeO₂ |
|---|---|---|---|---|
| k | 9 | 30 | 32 | 37 |
| Eg (eV) | 8.7 | 4.3 | 5.5 | 3.2 |

Please refer to FIG. 5 which shows the structure of the third embodiment of the present invention. The third embodiment is a MOS device 500. The MOS device 500, in order, includes a metal Al layer 501 (50 nm), an n-type InP substrate 502, an n-type In_{0.53}Ga_{0.47}As layer 503 with the doping concentration being 5*1017 cm⁻³ (100 nm), an aluminum oxide layer 504 (3 nm), a La₂O₃, Pr₆O₁₁ or CeO₂ layer 505 (6 nm) and a metal W layer 506 (50 nm). The MOS device 500 is used to enhance and improve the electrical property of the capacitor. The manufacturing method includes: (a) providing an n-type In_{0.53}Ga_{0.47}As layer disposed on an n-type InP substrate; (b) processing the surface of the n-type In_{0.53}Ga_{0.47}As layer to facilitate the deposition or the sputtering of aluminum oxide; (c) depositing or sputtering La₂O₃, Pr₆O₁₁ or CeO₂ on the aluminum oxide; (d) rapidly annealing; (e) sputtering gate metal W on the La₂O₃, Pr₆O₁₁ or CeO₂; (f) etching the metal W to form a gate electrode; and (g) sputtering metal Al on the backside of the n-type InP substrate.

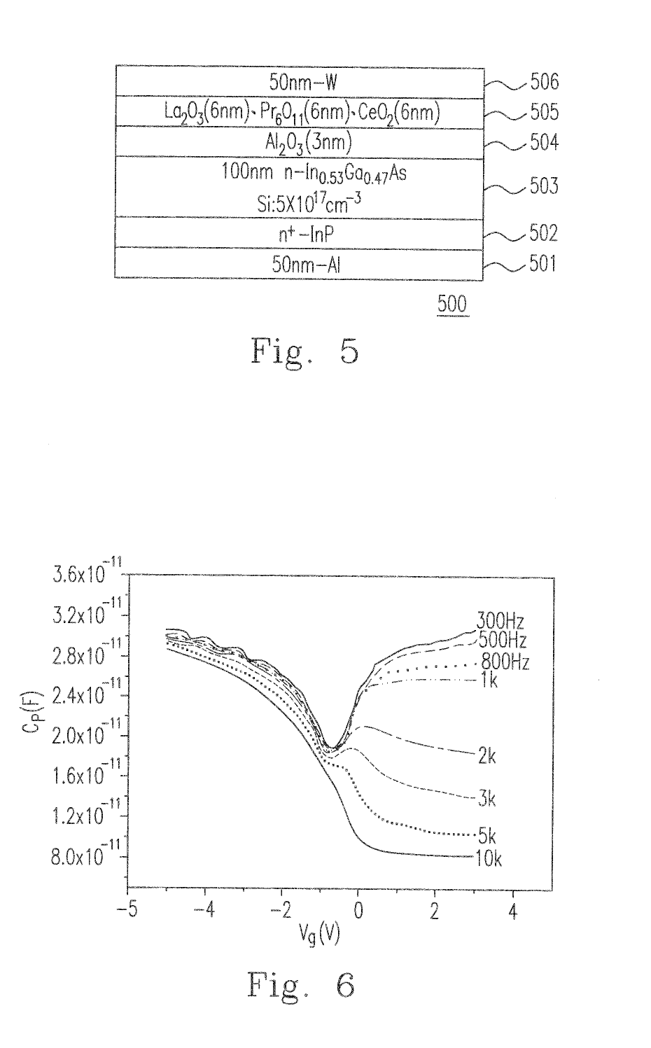

Please refer to FIG. 6 which shows the Capacitance-Voltage (C-V) curve diagram of the Al₂O₃/In_{0.53}Ga_{0.47}As MOS. In FIG. 6, it could be known that the capacitance in the accumulation region for the capacitor is getting higher represents the dielectric constant of the oxide is getting higher, and that the capacitance in the strong inversion region is getting higher represents the MOS device has a stronger inversion property so that the device will have more carriers when manufacturing the MOS FET device. In other words, using the semiconductor device provided in the present invention will not have the problem of failure of electrical property or a higher current leakage due to the inter-reaction of atoms. Furthermore, the semiconductor structure provided in the present invention needs only 1 nm aluminum oxide to prevent/inhibit the inter-reaction of atoms between a semiconductor layer and a dielectric layer. Up to now, there is no such thin oxide layer to prevent/inhibit the inter-reaction of atoms between a semiconductor layer and a dielectric layer. Therefore, the present invention is a big breakthrough for improving the EOT of the oxide layer of the semiconductor device, especially to a III-V semiconductor layer and a lanthanide oxide layer. Moreover, the present invention can have various thickness sets, such as 5 nm La₂O₃/1 nm Al₂O₃, 7 nm Pr₆O₁₁/2 nm Al₂O₃, 6 nm Nd₂O₃/3 nm Al₂O₃, and so on. In addition, the further technical feature lies in that using lanthanide oxide as a dielectric layer and lanthanide oxide as a barrier to improve the EOT of the semiconductor device.

There are still other embodiments, which are described as follows.

1. A metal-oxide-semiconductor device, including: a III-V semiconductor layer; an aluminum oxide layer formed on the III-V semiconductor layer; and a lanthanide oxide layer formed on the aluminum oxide layer.

2. The metal-oxide-semiconductor device as described in Embodiment 1 further including a substrate, wherein the III-V semiconductor layer is disposed on the substrate.

3. The metal-oxide-semiconductor device as described in Embodiment 2 further including a metal back contact, wherein the substrate has a backside, and the metal back contact is disposed on the backside of the substrate.

4. The metal-oxide-semiconductor device as described in Embodiment 1 further including a metal layer disposed on the lanthanide oxide layer.

5. The metal-oxide-semiconductor device as described in Embodiment 1, wherein the III-V semiconductor layer is an InₓGa₁₋ₓAs layer and the lanthanide oxide layer is one selected from a group consisting of a La₂O₃ layer, a Pr₆O₁₁ layer and a CeO₂ layer.

6. The metal-oxide-semiconductor device as described in Embodiment 1, wherein the aluminum oxide layer has a thickness of no less than 1 nm and the lanthanide oxide layer has a thickness of no less than 5 nm.

7. A semiconductor device, including: a semiconductor layer; a dielectric layer disposed on the semiconductor layer, wherein there is an inter-reaction of atoms between the semiconductor layer and the dielectric layer; and an aluminum oxide layer disposed between the semiconductor layer and the dielectric layer so as to inhibit the inter-reaction of atoms between the semiconductor layer and the dielectric layer.

8. The semiconductor device as described in Embodiment 7 further including a substrate, wherein the semiconductor layer is disposed on the substrate.

9. The semiconductor device as described in Embodiment 8 further including a metal back contact, wherein the substrate has a backside, and the metal back contact is disposed on the backside of the substrate.

10. The semiconductor device as described in Embodiment 7 further including a metal layer disposed on the dielectric layer.

11. The semiconductor device as described in Embodiment 7, wherein the dielectric layer is a lanthanide oxide layer and the semiconductor layer is a III-V semiconductor layer.

12. The semiconductor device as described in Embodiment 11, wherein the III-V semiconductor layer is an InₓGa₁₋ₓAs layer and the lanthanide oxide layer is one selected from a group consisting of a La₂O₃ layer, a Pr₆O₁₁ layer and a CeO₂ layer.

13. The semiconductor device as described in Embodiment 11, wherein the lanthanide oxide layer has a thickness of no less than 5 nm.

14. The semiconductor device as described in Embodiment 7, wherein the aluminum oxide layer has a thickness of no less than 1 nm.

15. A method of manufacturing a semiconductor device, including steps of: providing a semiconductor layer and a dielectric layer; and forming an aluminum oxide layer between the semiconductor layer and the dielectric layer so as to prevent an inter-reaction of atoms between the semiconductor layer and the dielectric layer.

16. The method as described in Embodiment 15, wherein the semiconductor layer has a surface, further including steps of: processing the surface of the semiconductor layer; forming the aluminum oxide layer on the processed surface of the semiconductor layer; and forming the dielectric layer on the aluminum oxide layer.

17. The method as described in Embodiment 15, wherein the semiconductor layer is a III-V semiconductor and the dielectric layer is a lanthanide oxide layer.

While the invention has been described in terms of what are presently considered to be the most practical and preferred embodiments, it is to be understood that the invention need not be limited to the disclosed embodiments. On the contrary, it is intended to cover various modifications and similar arrangements included within the spirit and scope of the appended claims, which are to be accorded with the broadest interpretation so as to encompass all such modifications and similar structures. Therefore the above description and illustration should not be taken as limiting the scope of the present invention which is defined by the appended claims.

What is claimed is:

1. A metal-oxide-semiconductor device, comprising:
a III-V semiconductor layer;
an aluminum oxide layer formed on the III-V semiconductor layer; and
a lanthanide oxide layer formed on the aluminum oxide layer.

2. The metal-oxide-semiconductor device as claimed in claim 1 further comprising a substrate, wherein the III-V semiconductor layer is disposed on the substrate.

3. The metal-oxide-semiconductor device as claimed in claim 2 further comprising a metal back contact, wherein the substrate has a backside, and the metal back contact is disposed on the backside of the substrate.

4. The metal-oxide-semiconductor device as claimed in claim 1 further comprising a metal layer disposed on the lanthanide oxide layer.

5. The metal-oxide-semiconductor device as claimed in claim 1, wherein the III-V semiconductor layer is an InₓGa₁₋ₓAs layer and the lanthanide oxide layer is one selected from a group consisting of a La₂O₃ layer, a Pr₆O₁₁ layer and a CeO₂ layer.

6. The metal-oxide-semiconductor device as claimed in claim 1, wherein the aluminum oxide layer has a thickness of no less than 1 nm and the lanthanide oxide layer has a thickness of no less than 5 nm.

7. A semiconductor device, comprising:
a semiconductor layer;
a dielectric layer disposed on the semiconductor layer, wherein there is an inter-reaction of atoms between the semiconductor layer and the dielectric layer; and
an aluminum oxide layer disposed between the semiconductor layer and the dielectric layer so as to inhibit the inter-reaction of atoms between the semiconductor layer and the dielectric layer.

8. The semiconductor device as claimed in claim 7 further comprising a substrate, wherein the semiconductor layer is disposed on the substrate.

9. The semiconductor device as claimed in claim 8 further comprising a metal back contact, wherein the substrate has a backside, and the metal back contact is disposed on the backside of the substrate.

10. The semiconductor device as claimed in claim 7 further comprising a metal layer disposed on the dielectric layer.

11. The semiconductor device as claimed in claim 7, wherein the dielectric layer is a lanthanide oxide layer and the semiconductor layer is a III-V semiconductor layer.

12. The semiconductor device as claimed in claim 11, wherein the III-V semiconductor layer is an InₓGa₁₋ₓAs layer and the lanthanide oxide layer is one selected from a group consisting of a La₂O₃ layer, a Pr₆O₁₁ layer and a CeO₂ layer.

13. The semiconductor device as claimed in claim 11, wherein the lanthanide oxide layer has a thickness of no less than 5 nm.

14. The semiconductor device as claimed in claim 7, wherein the aluminum oxide layer has a thickness of no less than 1 nm.

15. A method of manufacturing a semiconductor device, comprising steps of:
providing a semiconductor layer and a dielectric layer; and
forming an aluminum oxide layer between the semiconductor layer and the dielectric layer so as to prevent an inter-reaction of atoms between the semiconductor layer and the dielectric layer.

16. The method as claimed in claim 15, wherein the semiconductor layer has a surface, further comprising steps of:
processing the surface of the semiconductor layer;
forming the aluminum oxide layer on the processed surface of the semiconductor layer; and
forming the dielectric layer on the aluminum oxide layer.

17. The method as claimed in claim 15, wherein the semiconductor layer is a III-V semiconductor and the dielectric layer is a lanthanide oxide layer.
